(19) United States
(12) Patent Application Publication
(10) Pub. No.: US 2025/0286523 A1
(43) Pub. Date: Sep. 11, 2025

(54) POWER AMPLIFIERS WITH ADJUSTABLE SUPPLY VOLTAGE TO DYNAMICALLY CONTROL SATURATED OUTPUT POWER

(71) Applicant: Skyworks Solutions, Inc., Irvine, CA (US)

(72) Inventors: Grant Darcy Poulin, Carp (CA); Andrew Raymond Chen, Newton, MA (US)

(21) Appl. No.: 19/040,596

(22) Filed: Jan. 29, 2025

Related U.S. Application Data
(60) Provisional application No. 63/563,141, filed on Mar. 8, 2024.

(51) Int. Cl. H03F 3/24; H04B 1/00; H04W 52/52; H04W 84/12; H04W 88/08

(52) U.S. Cl. CPC H03F 3/245; H04W 52/52; H03F 2200/451; H04B 1/0064; H04W 84/12; H04W 88/08

(57) ABSTRACT

Apparatus and methods using an adjustable supply voltage to dynamically control saturated output power (Psat) of a power amplifier are disclosed. In certain embodiments, a front-end module includes a power amplifier that amplifies an RF transmit signal and a supply control switch this is coupled to a feedback network of a DC-to-DC converter. The supply control switch receives a control signal for adjusting Psat from a control circuit, which can be part of a Wi-Fi system controller.

### CROSS-REFERENCE TO RELATED APPLICATIONS

This application claims the benefit of priority under 35 U.S.C. § 119 of U.S. Provisional Patent Application No. 63/563,141, filed Mar. 8, 2024 and titled “POWER AMPLIFIERS WITH ADJUSTABLE SUPPLY VOLTAGE TO DYNAMICALLY CONTROL SATURATED OUTPUT POWER,” which is herein incorporated by reference in its entirety.

### BACKGROUND

### Field

Embodiments of the invention relate to electronic systems, and in particular, to radio frequency (RF) electronics.

### Description of the Related Technology

Power amplifiers are used in RF communication systems to amplify RF signals for transmission via antennas.

Examples of RF communication systems with one or more power amplifiers include, but are not limited to, mobile phones, tablets, base stations, access points, customer-premises equipment (CPE), laptops, and wearable electronics. For example, in wireless devices that communicate using a cellular standard, a wireless local area network (WLAN) standard (such as an 802.11 standard for Wi-Fi), and/or any other suitable communication standard, a power amplifier can be used for RF signal amplification. An RF signal can have a frequency in the range of about 30 kilohertz (kHz) to 300 gigahertz (GHz).

### SUMMARY

In certain embodiments, an access point for a Wi-Fi network is disclosed. The access point includes a DC-to-DC converter configured to generate a supply voltage based on a feedback signal received from a feedback network, a front-end module including a supply control switch coupled to the feedback network and a power amplifier powered by the supply voltage and configured to amplify a radio frequency transmit signal, and a system controller including a control circuit configured to provide a control signal to the supply control switch. The supply control switch is operable to control a voltage level of the supply voltage based on the control signal.

In some embodiments, the supply control switch controls an amount of saturated output power of the power amplifier based on the control signal.

In various embodiments, the feedback network is included on the front-end module.

In several embodiments, the feedback network is external to the front-end module.

In some embodiments, the supply control switch controls a resistance of the feedback network to control a voltage level of the feedback signal.

In several embodiments, the feedback network includes a selectable resistor in series with the supply control switch. According to a number of embodiments, the feedback network further includes a first voltage divider resistor connected between the supply voltage and a feedback input to the DC-to-DC converter, and a second voltage divider resistor connected between the feedback input and a ground voltage. In accordance with various embodiments, the selectable resistor and the supply control switch are in series between the supply voltage and the feedback input.

In some embodiments, the supply control switch sets the supply voltage to a first supply voltage level for a first value of the control signal, and to a second supply voltage level for a second value of the control signal.

In several embodiments, the control circuit sets a value of the control signal based on a modulation and coding scheme index of the radio frequency transmit signal.

In various embodiments, the control circuit sets a value of the control signal based on detecting a simultaneous transmission of the radio frequency transmit signal and reception of a radio frequency receive signal.

In several embodiments, the radio frequency transmit signal operates in a Wi-Fi 5 GHz band or a Wi-Fi 6 GHz band.

In some embodiments, the control signal further controls at least one of a bias or a load line of the power amplifier.

In various embodiments, the DC-to-DC converter includes a switching regulator.

In several embodiments, the DC-to-DC converter includes a low dropout regulator.

In certain embodiments, the present disclosure relates to a front-end module. The front-end module includes a power amplifier powered by a supply voltage from a DC-to-DC converter, the power amplifier configured to amplify a radio frequency transmit signal. The front-end module further includes a supply control switch coupled to a feedback network for setting a voltage level of the supply voltage from the DC-to-DC converter. The supply control switch is operable to receive a control signal from a control circuit of a system controller, and to control the voltage level of the supply voltage based on the control signal.

In various embodiments, the supply control switch controls an amount of saturated output power of the power amplifier based on the control signal.

In several embodiments, the feedback network is included on the front-end module.

In some embodiments, the feedback network is external to the front-end module.

In several embodiments, the supply control switch controls a resistance of the feedback network to control a voltage level of the feedback signal.

In various embodiments, the feedback network includes a selectable resistor in series with the supply control switch. According to a number of embodiments, the feedback network further includes a first voltage divider resistor connected between the supply voltage and a feedback input to the DC-to-DC converter, and a second voltage divider resistor connected between the feedback input and a ground voltage. In accordance with several embodiments, the selectable resistor and the supply control switch are in series between the supply voltage and the feedback input.

In some embodiments, the supply control switch sets the supply voltage to a first supply voltage level for a first value of the control signal, and to a second supply voltage level for a second value of the control signal.

In various embodiments, the radio frequency transmit signal operates in a Wi-Fi 5 GHz band or a Wi-Fi 6 GHz band.

In several embodiments, the control signal further controls at least one of a bias or a load line of the power amplifier.

In certain embodiments, the present disclosure relates to a method of radio frequency signal communication. The method includes receiving a feedback signal from a feedback network at a feedback input of a DC-to-DC converter, generating a supply voltage based on the feedback signal using the DC-to-DC converter, powering a power amplifier that amplifies a radio frequency transmit signal using the supply voltage and that is included on a front-end module, providing a control signal to a supply control switch that is coupled to the feedback network, the supply control switch included on the front-end module, and controlling a voltage level of the supply voltage based on the control signal using the supply control switch.

In various embodiments, the method further includes controlling an amount of saturated output power of the power amplifier based on the control signal using the supply control switch controls.

In several embodiments, the feedback network is included on the front-end module.

In some embodiments, the feedback network is external to the front-end module.

In various embodiments, the method further includes controlling a resistance of the feedback network to control a voltage level of the feedback signal using the supply control switch.

In several embodiments, the feedback network includes a selectable resistor in series with the supply control switch. According to a number of embodiments, the feedback network further includes a first voltage divider resistor connected between the supply voltage and a feedback input to the DC-to-DC converter, and a second voltage divider resistor connected between the feedback input and a ground voltage. In accordance with various embodiments, the selectable resistor and the supply control switch are in series between the supply voltage and the feedback input.

In some embodiments, the method further includes setting the supply voltage to a first supply voltage level for a first value of the control signal using the supply control switch, and setting the supply voltage to a second supply voltage level for a second value of the control signal using the supply control switch.

In several embodiments, the method further includes setting a value of the control signal based on a modulation and coding scheme index of the radio frequency transmit signal using the control circuit.

In various embodiments, the method further includes setting a value of the control signal based on detecting a simultaneous transmission of the radio frequency transmit signal and reception of a radio frequency receive signal.

In some embodiments, the radio frequency transmit signal operates in a Wi-Fi 5 GHz band or a Wi-Fi 6 GHz band.

In several embodiments, the method further includes controlling at least one of a bias or a load line of the power amplifier using the control signal.

In various embodiments, the DC-to-DC converter includes a switching regulator.

In some embodiments, the DC-to-DC converter includes a low dropout regulator.

### BRIEF DESCRIPTION OF THE DRAWINGS

Embodiments of this disclosure will now be described, by way of non-limiting example, with reference to the accompanying drawings.

FIG. 1 is a schematic diagram of one embodiment of a Wi-Fi network.

FIG. 2 is a schematic diagram of one example of frequency separation between Wi-Fi 5 GHz and Wi-Fi 6 GHz frequency bands.

FIG. 3A is a schematic diagram of one example of self-interference for a Wi-Fi access point simultaneously transmitting on a Wi-Fi 6 GHz frequency band and receiving on a Wi-Fi 5 GHz frequency band.

FIG. 3B is a schematic diagram of one example of self-interference for a Wi-Fi access point simultaneously receiving on a Wi-Fi 6 GHz frequency band and transmitting on a Wi-Fi 5 GHz frequency band.

FIG. 4 is a schematic diagram of a Wi-Fi access point according to one embodiment.

FIG. 5 is a schematic diagram of a DC-to-DC converter according to one embodiment.

FIG. 6A is a schematic diagram of one embodiment of a power amplifier system with adjustable supply voltage for dynamically controlling saturated output power (Psat).

FIG. 6B is a schematic diagram of another embodiment of a power amplifier system with adjustable supply voltage for dynamically controlling Psat.

FIG. 7A is a schematic diagram of one embodiment of a packaged module.

FIG. 7B is a schematic diagram of a cross-section of the packaged module of FIG. 7A taken along the lines 7B-7B.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

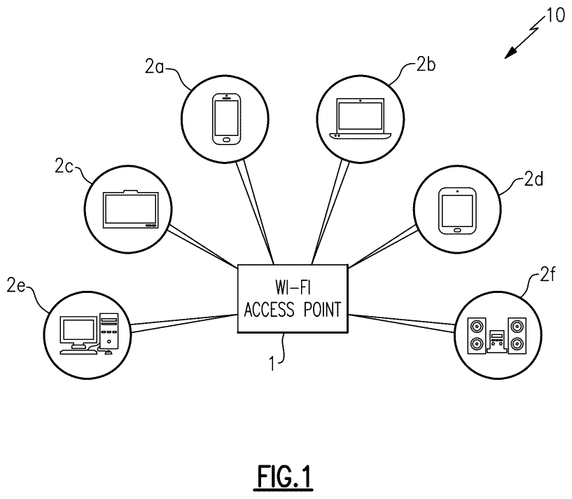

FIG. 1 is a schematic diagram of one embodiment of a Wi-Fi network 10. The Wi-Fi network 10 includes a Wi-Fi access point 1 and various examples of Wi-Fi enabled equipment, including a mobile phone 2a, a laptop 2b, a smart television 2c, a tablet 2d, a desktop computer 2e, and a smart audio system 2f.

Although specific examples of Wi-Fi enabled equipment are illustrated in FIG. 1, a Wi-Fi network can include Wi-Fi enabled equipment of other numbers and/or types. Thus, although various examples of Wi-Fi enabled equipment are shown, the teachings herein are applicable to a wide variety of types of equipment, including, but not limited to, mobile phones, tablets, laptops, IoT devices, wearable electronics, customer premises equipment (CPE), wireless-connected vehicles, wireless relays, and/or a wide variety of other communication devices. Furthermore, although one Wi-Fi access point is depicted, multiple Wi-Fi access points can be included in a Wi-Fi network.

The illustrated Wi-Fi network 10 of FIG. 1 supports communication over Wi-Fi 7 (IEEE 802.11be) as well as to subsequent Wi-Fi technologies such as Wi-Fi 8 and beyond.

Wi-Fi 7, also referred to as IEEE 802.11be or Extremely High Throughput (EHT) Wi-Fi, is a recent amendment of the IEEE 802.11 standard. Wi-Fi 7 is built upon 802.11ax and focuses on WLAN indoor and outdoor operation with stationary and pedestrian speeds. Wi-Fi 7 supports a number of frequency bands, including Wi-Fi 2.4 GHz, Wi-Fi 5 GHZ, and Wi-Fi 6 GHz.

The Wi-Fi 5 GHz frequency band spans from 5170 megahertz (MHz) to 5895 MHz and corresponds to Unlicensed National Information Infrastructure (UNII) frequency ranges 1, 2A, 2B, 3, and 4. Additionally, the Wi-Fi 6 GHz frequency band spans from 5945 MHz to 7125 MHz and corresponds to UNII frequency ranges 5, 6, 7, and 8. The UNII-4 frequency range operates from 5850 MHz to 5895 MHz, and was designated in 2021 by the Federal Communications Commission (FCC) for use as additional Wi-Fi spectrum in the US.

Various communication links of the Wi-Fi network 10 have been depicted in FIG. 1. The communication links can be duplexed in a wide variety of ways, including, for example, using time-division duplexing (TDD). TDD is a type of radio frequency communications that uses about the same frequency for transmitting and receiving signals, and in which transmit and receive communications are switched in time. TDD can provide efficient use of spectrum and variable allocation of throughput between transmit and receive directions.

Advanced feature support for Wi-Fi 7 and beyond specifies Wi-Fi access points (and in certain instances, Wi-Fi enabled equipment) to support simultaneous transmit and receive (STR) over two different Wi-Fi frequency bands.

Thus, as part of the Wi-Fi 7 standard (and future versions), all access points must support STR operation in at least two frequency bands. One desirable STR split is to use the Wi-Fi 5 GHz band (UNII-1 to UNII-4) for the first band and the Wi-Fi 6 GHz band (UNII-5 to UNII-8) as the second band.

Wi-Fi 7 supports complex modulation and coding schemes (MCS) that can be selected by the Wi-Fi access point 1 based on various parameters associated with the WiFi network 10. A given MCS can have different modulation type, coding rate, number of spatial streams, channel width, guard interval, and/or other properties. Table 1 below provides an example of MCS index, modulation type and coding rate for an example rate set for Wi-Fi 7 (IEEE 802.11be).

TABLE 1

| MCS Index | Modulation Type | Coding Rate |
|---|---|---|
| MCS0 | BPSK | ½ |
| MCS1 | QPSK | ½ |
| MCS2 | QPSK | ¾ |
| MCS3 | 16-QAM | ½ |
| MCS4 | 16-QAM | ¾ |
| MCS5 | 64-QAM | ⅔ |
| MCS6 | 64-QAM | ¾ |
| MCS7 | 64-QAM | ⅚ |
| MCS8 | 256-QAM | ¾ |
| MCS9 | 256-QAM | ⅚ |
| MCS10 | 1024-QAM | ¾ |
| MCS11 | 1024-QAM | ⅚ |
| MCS12 | 4096-QAM | ¾ |
| MCS13 | 4096-QAM | ⅚ |

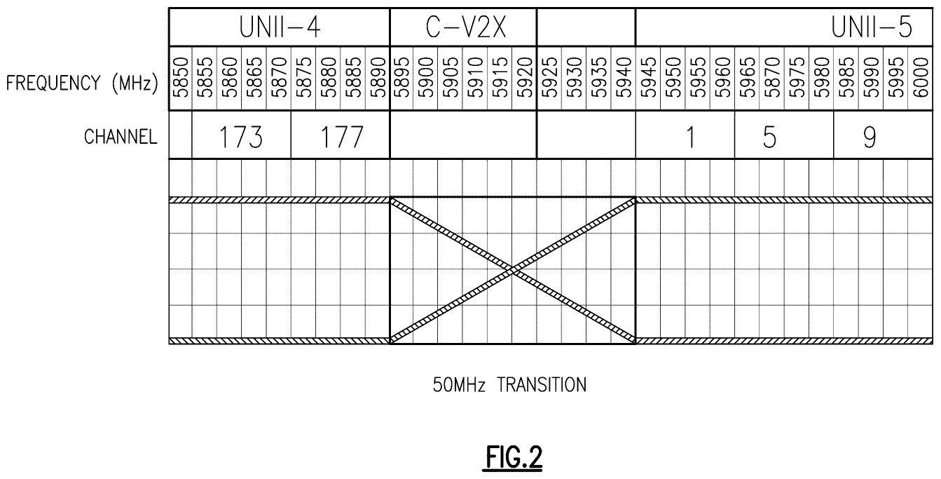

FIG. 2 is a schematic diagram of one example of frequency separation between Wi-Fi 5 GHz and Wi-Fi 6 GHz frequency bands. As depicted in FIG. 2, only a 50 MHz frequency spacing is present between the upper edge of the Wi-Fi 5 GHz frequency band (upper edge of UNII-4) and the bottom edge of the Wi-Fi 6 GHz frequency band (lower edge of UNII-5).

In view of the small 50 MHz frequency spacing, self-interference between the Wi-Fi 5 GHz band and the Wi-Fi 6 GHz band is a significant problem when these bands are used for STR operation.

For example, self-interference can arise from transmit noise from a Wi-Fi transmitter falling into the receive band of a co-located Wi-Fi receiver, resulting in a reduction of range and throughput.

To support STR operation, stringent filtering is desired for both the Wi-Fi 5 GHz band and the Wi-Fi 6 GHz band.

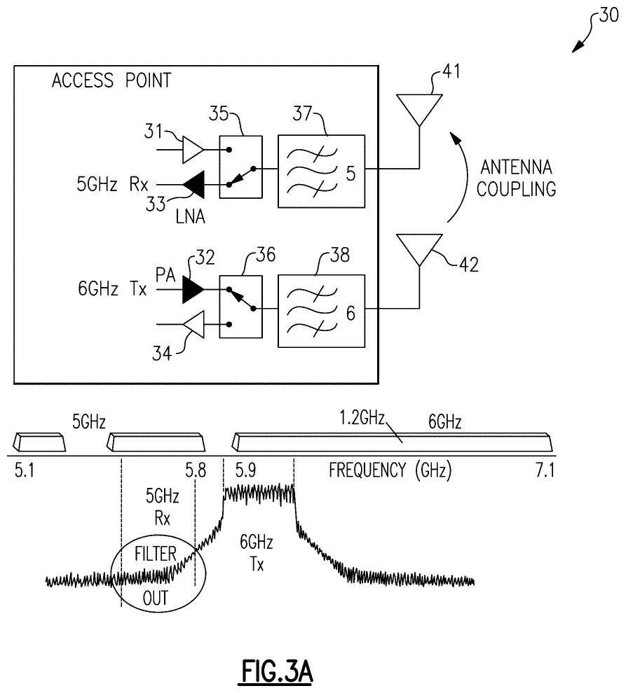

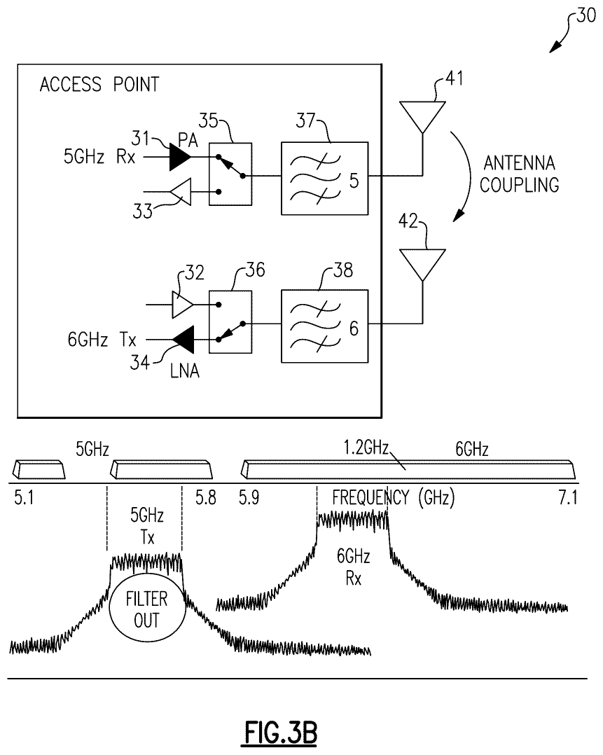

FIG. 3A is a schematic diagram of one example of self-interference for a Wi-Fi access point 30 simultaneously transmitting on a Wi-Fi 6 GHz frequency band and receiving on a Wi-Fi 5 GHz frequency band. FIG. 3B is a schematic diagram of one example of self-interference for the Wi-Fi access point 30 simultaneously receiving on a Wi-Fi 6 GHz frequency band and transmitting on a Wi-Fi 5 GHz frequency band.

With reference to FIGS. 3A and 3B, the Wi-Fi access point 30 includes a 5 GHz power amplifier (PA) 31, a 6 GHz power amplifier 32, a 5 GHz low noise amplifier (LNA) 33, a 6 GHz LNA 34, a 5 GHz transmit/receive (T/R) switch 35, a 6 GHz T/R switch 36, a 5 GHz band filter 37, a 6 GHz band filter 38, a 5 GHz antenna 41, and a 6 GHz antenna 42.

The 5 GHz band filter 37 reduces out of band (OOB) noise that would fall in the 6 GHz receive band and cause de-sensitization. The 5 GHz band filter 37 also filters out the 6 GHz transmit signal that can degrade the linearity of the 5 GHz LNA 33.

In the example of FIG. 3A, the 6 GHz power amplifier 32 is transmitting while the 5 GHz LNA 33 is simultaneously receiving as part of STR operation for Wi-Fi 7. The 6 GHz band filter 38 is depicted as rejecting OOB noise from the 6 GHz transmit signal that degrades the noise floor and causes desensitization of the 5 GHz LNA 33.

The 6 GHz band filter 38 reduces OOB noise that would fall in the 5 GHz receive band and cause de-sensitization. The 6 GHz band filter 38 also filters out the 5 GHz transmit signal that can degrade the linearity of the 6 GHz LNA 34.

In the example of FIG. 3B, the 5 GHz power amplifier 31 is transmitting while the 6 GHz LNA 34 is simultaneously receiving as part of STR operation for Wi-Fi 7. The 6 GHz band filter 38 is depicted as rejecting 5 GHz transmit signal leakage that can otherwise saturate the 6 GHz LNA 34 and result in desensitization.

Thus, it is highly desirable to have a pair of filters than can operate to allow simultaneous UNII-4/UNII-5 operation for STR. However, such filters are extremely challenging to fabricate given the 50 MHz band separation between the upper edge of UNII-4 and the lower edge of UNII-5.

For example, in one application, the 5 GHz band filter 37 is specified to pass a signal at 5895 MHz with less than 2 decibels (2 dB) of insertion loss while providing rejection of more than 70 dB at 5945 MHz, which is only 50 MHz away. In another application, the 6 GHz band filter 38 is specified to pass a signal at 5945 MHz with less than 2 dB of insertion loss while providing rejection of more than 70 dB at 5895 MHz, which is only 50 MHz away.

Achieving greater than 70 dB of rejection with only a 50 MHz transition band over process and temperature may be infeasible for existing filter technology, such as surface acoustic wave (SAW) filters and/or bulk acoustic wave (BAW) filters.

Examples of Power Amplifiers with Adjustable Supply Voltage for Dynamic Psat Control

A power amplifier is typically designed with a maximum allowed total power available and a maximum allowed power dissipation. This maximum power is consumed when the power amplifier operates at mask-limited power.

For example, for Wi-Fi 7 (IEEE 802.11be), mask limited power uses MCS0 index associated with bipolar phase shift keying modulation (BPSK). MCS0 is typically transmitted at power levels about 4.5 dB backed off from Psat.

Once Psat is fixed, other MCS levels (for instance, MCS13/4096QAM) must be backed off further so that the power amplifier is linear enough to support the higher order modulation. For example, MCS13 typically operates about 10 dB backed off from Psat. When the power is backed off by 10 dB to accommodate MCS13 operation, the power consumption is significantly reduced.

To address such limitations, it is desirable to provide a Psat boosting mode in which the Psat of the power amplifier is selectively increased. For example, the Psat boosting mode can be activated for high MCS levels like MCS13/4096QAM to dynamically increase Psat. Thus, the power amplifier can consume more power at such high MCS levels (for instance, at MCS13) up to the level that was consumed at mask limited power (for instance, MCS0). Thus, the power for high MCS levels can be increased without exceeding the maximum power available to the power amplifier.

The Psat boosting mode can also be useful for other operating conditions. In one example, the Psat boosting mode can be used for to selectively reduce out-of-band (OOB) to meet difficult STR scenarios. Such challenging STR scenarios can be associated with STR on Wi-Fi 5 GHz and Wi-Fi 6 GHz bands. For example, difficult STR scenarios can be based on a power threshold (for example, transmit power greater than a threshold) and/or high channel bandwidths (for example, channel bandwidths greater than a threshold such as 40 MHz or higher).

Thus, the Psat boosting mode can be selected based on MCS level, STR scenario, and/or based on other operating conditions as desired.

Provided herein are RF communication systems in which an adjustable supply voltage of a power amplifier is used to dynamically control an amount of saturated output power (Psat) of the power amplifier. In certain embodiments, a front-end module includes a power amplifier that amplifies an RF transmit signal and a supply control switch this is coupled to a feedback network of a DC-to-DC converter. The supply control switch receives a control signal for adjusting Psat from a control circuit, which can be part of a Wi-Fi system controller.

In certain implementations, during normal operation the control signal sets the supply control switch in a first state to operate the power amplifier with a first supply voltage level associated with a first or nominal Psat level. However, when desired (for instance, for high MCS level or STR operating scenarios), the control circuit uses the control signal to set the supply control switch in a second state to operate the power amplifier with a second supply voltage level associated with a second or increased Psat level in which the power amplifier operates with reduced OOB noise and heightened linearity.

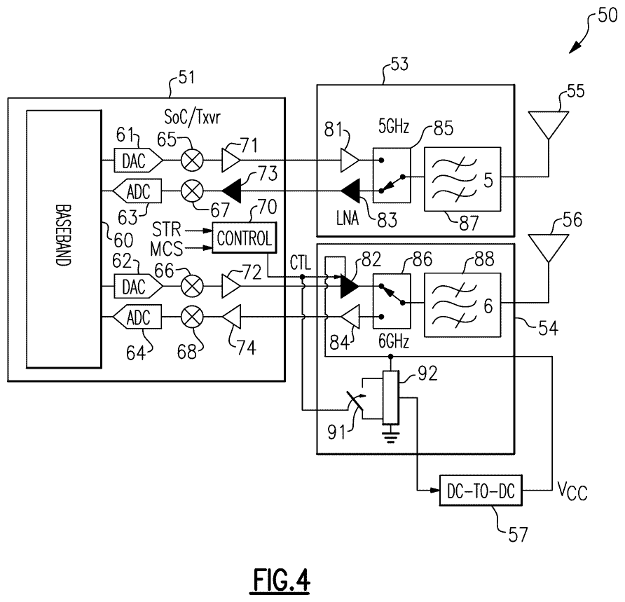

FIG. 4 is a schematic diagram of a Wi-Fi access point 50 according to one embodiment. The Wi-Fi access point 50 includes a transceiver 51 (for instance, a Wi-Fi system controller or SoC), a 5 GHz front-end module 53, a 6 GHz front-end module 54, a 5 GHz antenna 55, a 6 GHz antenna 56, and a DC-to-DC converter 57.

In the illustrated embodiment, the transceiver 51 includes a baseband circuit 60, a 5 GHz transmit-path digital-to-analog converter (DAC) 61, a 6 GHz transmit-path DAC 62, a 5 GHz receive-path analog-to-digital converter (ADC) 63, a 6 GHz receive-path ADC 64, a 5 GHz transmit-path mixer 65, a 6 GHz transmit-path mixer 66, a 5 GHz receive-path mixer 67, a 6 GHz receive-path mixer 68, an STR control circuit 70, a 5 GHz transmit amplifier 71, a 6 GHz transmit amplifier 72, a 5 GHz receive amplifier 73, and a 6 GHz receive amplifier 74.

With continuing reference to FIG. 4, the 5 GHz front-end module 53 includes a 5 GHz power amplifier 81, a 5 GHz LNA 83, a 5 GHz T/R switch 85, and a 5 GHz band filter 87 (for instance, a BAW filter). Additionally, the 6 GHz front-end module 54 includes a 6 GHz power amplifier 82, a 6 GHz LNA 84, a 6 GHz T/R switch 86, a 6 GHz band filter 88 (for instance, a BAW filter), a supply control switch 91, and a feedback network 92.

As shown in FIG. 4, the 6 GHz power amplifier 82 receives a control signal CTL from the control circuit 70 of the transceiver 51 (for instance, Wi-Fi system controller). The control signal CTL can be used to control various characteristics (for instance, a bias and/or load line impedance) of the 6 GHz power amplifier 82. The control signal CTL is also provided to the supply control switch 91, which is coupled to the feedback network 92.

In the illustrated embodiment, the feedback network 92 is formed on the 6 GHz front-end module 54 and thus is on the same module as the supply control switch 91. However, the feedback network 92 can also be formed externally to the module that includes the supply control switch 91, for instance, on another module and/or formed on a circuit board to which the module is attached.

As shown in FIG. 4, the DC-to-DC converter 57 generates the supply voltage V_{CC} based on a feedback signal received from the feedback network 92. Additionally, the supply control switch 91 is coupled to the feedback network 92 and receives the control signal CTL. The supply control switch 91 is operable to control a voltage level of the supply voltage V_{CC} based on the control signal CTL. The DC-to-DC converter 57 can be implemented in a variety of ways, including using a switching regulator or low dropout (LDO) regulator.

In FIG. 4, the control circuit 70 uses the control signal CTL to selectively increase the Psat of the 6 GHz power amplifier 82. In certain implementations, Psat is selectively increased based on at least one of an MCS index and/or an STR operating scenario.

Although not shown in FIG. 4, a similar control signal can be provided from the STR control circuit 70 to the 5 GHz power amplifier 81 to selectively increase the Psat of the 5 GHz power amplifier 81 for certain operating scenarios.

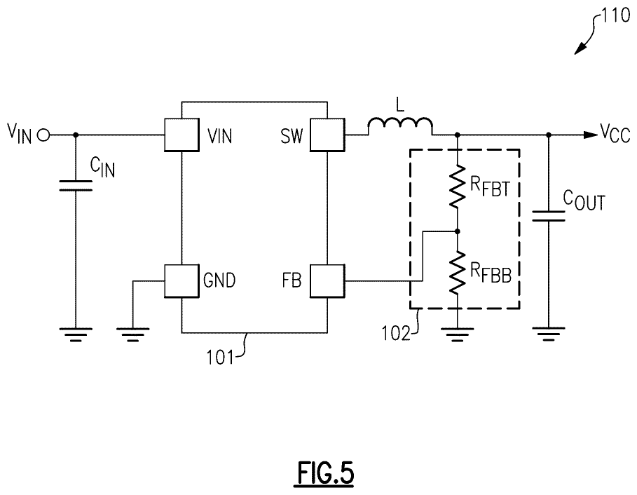

FIG. 5 is a schematic diagram of a DC-to-DC converter 110 according to one embodiment. The DC-to-DC converter 110 includes a switching regulator 101, an input capacitor C_{IN}, an output capacitor C_{OUT}, an inductor L, and a feedback network 102 that includes a top feedback resistor R_{FBT} and a bottom feedback resistor R_{FBB}.

Wi-Fi access points typically include several 5 GHz front-end modules (FEMs) and several 6 GHz FEMs. For example, certain Wi-Fi access points include 4 5 GHz FEMs and 4 6 GHz FEMs to enable multiple-input/multiple-output (MIMO) operation.

Certain access points receive an input voltage (for instance, a 12V supply voltage), which is converted by a DC-to-DC converter to a supply voltage (for instance, 5V) suitable for use by the FEMs.

In the illustrated embodiment, the switching regulator 101 includes an input pin VIN that receives the input voltage. The switching regulator 101 also includes a ground pin GND for receiving a ground voltage, a switcher output pin SW that is connected to the supply voltage V_{CC} through the inductor L, and a feedback pin FB that receives a feedback voltage from the feedback network 102.

As shown in FIG. 5, the top feedback resistor R_{FBT} and the bottom feedback resistor R_{FBB} of the feedback network 102 are connected in series between the supply voltage V_{CC} and the ground voltage as a voltage divider. The output of the voltage divider (corresponding to a node connecting the top feedback resistor R_{FBT} and the bottom feedback resistor R_{FBB}) generates a feedback voltage that is provided to the feedback pin FB of the switching regulator 101.

The feedback voltage controls the voltage level of the supply voltage V_{CC} generated by the DC-to-DC converter 110. In one example, the supply voltage V_{CC} is given by the equation (hereinafter Equation 1) V_{CC}=Vref*(1+R_{FBT}/R_{FBB}), where Vref is a reference voltage (for instance, a bandgap reference voltage).

In certain embodiments herein, a supply control switch on a FEM controls a feedback signal to a switching regulator. In this way, the FEM can control the DC supply voltage, and hence Psat of the power amplifier.

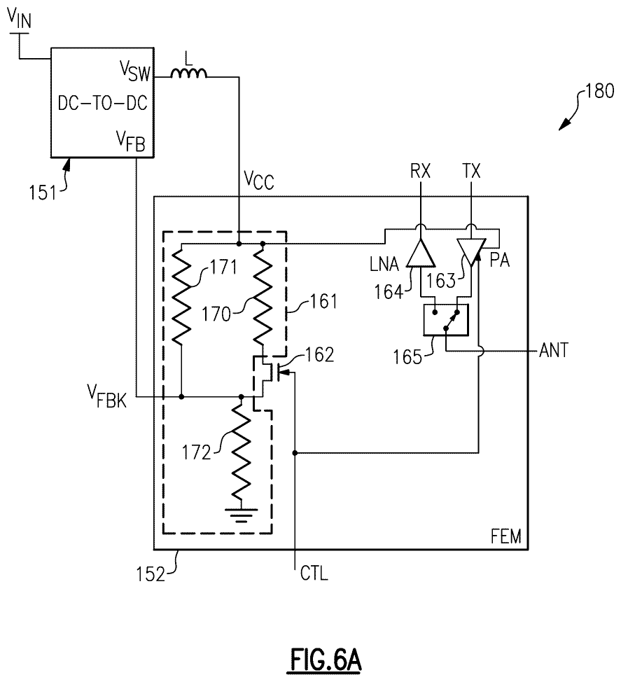

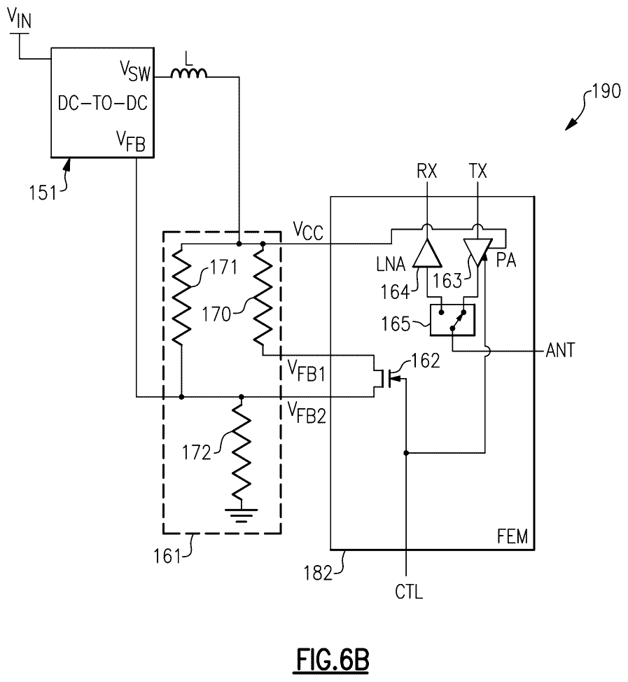

FIG. 6A is a schematic diagram of one embodiment of a power amplifier system 180 with adjustable supply voltage for dynamically controlling saturated output power (Psat). The power amplifier system 180 includes a DC-to-DC converter 151 and a front-end module (FEM) 152.

In the illustrated embodiment, the FEM 152 includes a feedback network 161, a supply control field-effect transistor (FET) switch 162, a power amplifier 163, a low noise amplifier 164, and a transmit/receive switch 165. As shown in FIG. 6A, the power amplifier 163 is powered by a supply voltage V_{CC}. In certain implementations, the supply voltage V_{CC} is also used to power at least one of the low noise amplifier 164 or the transmit/receive switch 165.

With continuing reference to FIG. 6A, the power amplifier 163 includes an input connected to a transmit terminal (TX) for receiving an RF transmit signal for amplification. The power amplifier 163 further includes an output connected to a first signal terminal of the transmit/receive switch 165. The low noise amplifier 164 includes an input connected to a second signal terminal of the transmit/receive switch 165 and an output connected to an a receive terminal RX. The transmit/receive switch 165 further includes an antenna terminal (ANT) for connected to an antenna.

The DC-to-DC converter 151 includes a feedback input (VFB) that receives a feedback voltage V_{FBK} from the feedback network 161, an inductor L, and a switcher output V_{SW} that is connected to the supply voltage V_{CC} of the FEM 152 through the inductor L. The DC-to-DC converter 151 controls a voltage level of the supply voltage V_{CC} based on the voltage level of the feedback voltage V_{FBK}. The DC-to-DC converter 151 can be implemented in a variety of ways, including using a switching regulator or an LDO regulator.

In the illustrated embodiment, the feedback network 161 includes a selectable resistor 170, a first voltage divider resistor 171, and a second voltage divider resistor 172. The first voltage divider resistor 171 and the second voltage divider resistor 172 are connected in series between the supply voltage V_{CC} and a ground voltage, and an output node connecting the first voltage divider resistor 171 to the second voltage divider resistor 172 generates the feedback voltage V_{FBK}. Additionally, the selectable resistor 170 and the supply control FET switch 162 are connected in series between the supply voltage V_{CC} and the output node.

As shown in FIG. 6A, the gate of the supply control FET switch 162 is controlled by a control signal CTL provided to the FEM 152. The control signal CTL can be provided from an SoC or Wi-Fi system controller.

Inside the FEM, the control signal CTL from the Wi-Fi system controller is received and used to adjust the feedback voltage V_{FBK} to the DC-to-DC converter 151.

The control signal CTL can also be used for other functions within the FEM 151. For example, in one embodiment, the control signal CTL is also used to adjust at least one of a bias or a load line of the power amplifier 163 to improve performance of the power amplifier 163 as the voltage level of the supply voltage V_{CC} is changed.

In the illustrated embodiment, only a single control pin can be used to receive the control signal CTL. The control signal CTL is used to turn on or off the supply control FET switch 162, which can be a discrete switch or integrated into a semiconductor die (for instance, a die on which the power amplifier 163, the low noise amplifier 164, and/or the transmit/receive switch 165 is formed). In one embodiment, the supply control FET switch 162 and the transmit/receive switch are each formed from silicon-on-insulator (SOI) metal-oxide-semiconductor (MOS) transistors on a common SOI die.

As the control signal CTL is changed, the voltage level of the supply voltage V_{CC} also changes. In one example, the DC-to-DC converter 151 delivers about 6V with the control signal CTL low and about 5V with the control signal CTL high.

The depicted power amplifier system 180 offers a number of advantages, including a compact implementation while also keeping the DC-to-DC converter 151 external to the FEM 152. For example, keeping the DC-to-DC converter 151 external to the FEM 152 allows the DC-to-DC converter 151 to be shared by multiple FEMs and inhibits the switching noise from the DC-to-DC converter 151 from leaking onto control lines or RF traces of the FEM 152.

FIG. 6B is a schematic diagram of another embodiment of a power amplifier system 190 with adjustable supply voltage for dynamically controlling Psat. The power amplifier system 190 includes a DC-to-DC converter 151, a feedback network 161, and a FEM 182.

The power amplifier system 190 of FIG. 6B is similar to the power amplifier system 180 of FIG. 6A, except that in the power amplifier system 190 of FIG. 6B the feedback network 161 is external to the FEM 182.

By implementing the power amplifier system 190 in this manner, improved flexibility is achieved as the architecture allows the values of the resistors to be adjusted to be compatible with different DC-to-DC converters. For example, different manufacturers can use different reference voltages in Equation 1 above, and if the reference voltage changes, then the resistor values must also change. As shown in FIG. 6B, the depicted configuration uses two pins (V_{FB1} and V_{FB2}) for coupling the supply control switch 162 to the feedback network 161.

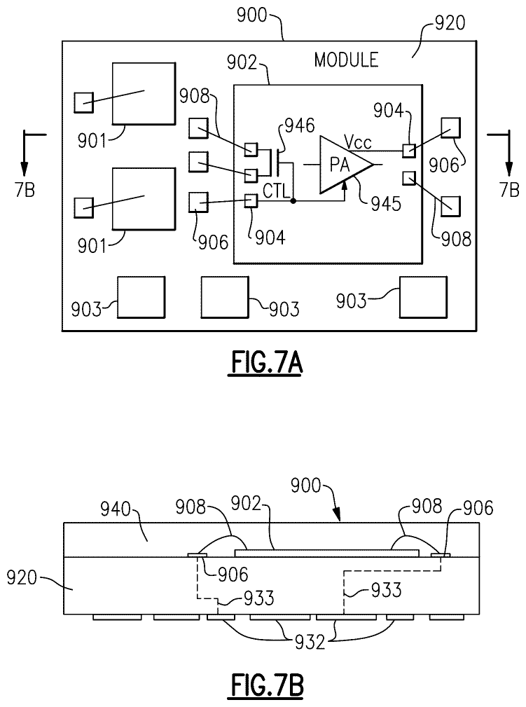

FIG. 7A is a schematic diagram of one embodiment of a packaged module 900. FIG. 7B is a schematic diagram of a cross-section of the packaged module 900 of FIG. 7A taken along the lines 7B-7B.

The packaged module 900 includes radio frequency components 901, a semiconductor die 902, surface mount devices 903, wirebonds 908, a package substrate 920, and an encapsulation structure 940. The package substrate 920 includes pads 906 formed from conductors disposed therein. Additionally, the semiconductor die 902 includes pins or pads 904, and the wirebonds 908 have been used to connect the pads 904 of the die 902 to the pads 906 of the package substrate 920.

The semiconductor die 902 includes a power amplifier 945, which can be implemented in accordance with any of the embodiments herein. As shown in FIG. 7A, the power amplifier 945 receives a supply control voltage V_{CC} and a control signal CTL over pins of the semiconductor die 902. In certain implementations, the control signal can be received from a Wi-Fi system controller, which can be external to the packaged module 900 or implemented on another die of the packaged module 900. The semiconductor die 902 also includes a supply control FET switch 946, which is controlled by the control signal CTL. The supply control FET switch 946 is coupled to a feedback network, which can be implemented on the module 900 (including in all or part on the die 902) and/or external to the module 900.

The packaging substrate 920 can be configured to receive a plurality of components such as radio frequency components 901, the semiconductor die 902 and the surface mount devices 903, which can include, for example, surface mount capacitors and/or inductors. In one implementation, the radio frequency components 901 include integrated passive devices (IPDs) and/or another die that includes a Wi-Fi system controller.

As shown in FIG. 7B, the packaged module 900 is shown to include a plurality of contact pads 932 disposed on the side of the packaged module 900 opposite the side used to mount the semiconductor die 902. Configuring the packaged module 900 in this manner can aid in connecting the packaged module 900 to a circuit board, such as a phone board of a mobile device. The example contact pads 932 can be configured to provide radio frequency signals, bias signals, and/or power (for example, a power supply voltage and ground) to the semiconductor die 902 and/or other components. As shown in FIG. 7B, the electrical connections between the contact pads 932 and the semiconductor die 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An access point for a Wi-Fi network, the access point comprising:
a DC-to-DC converter configured to generate a supply voltage based on a feedback signal received from a feedback network;
a front-end module including a supply control switch coupled to the feedback network and a power amplifier powered by the supply voltage and configured to amplify a radio frequency transmit signal; and
a system controller including a control circuit configured to provide a control signal to the supply control switch, the supply control switch operable to control a voltage level of the supply voltage based on the control signal.

2. The access point of claim 1 wherein the supply control switch controls an amount of saturated output power of the power amplifier based on the control signal.

3. The access point of claim 1 wherein the feedback network is included on the front-end module.

4. The access point of claim 1 wherein the feedback network is external to the front-end module.

5. The access point of claim 1 wherein the supply control switch controls a resistance of the feedback network to control a voltage level of the feedback signal.

6. The access point of claim 1 wherein the feedback network includes a selectable resistor in series with the supply control switch.

7. The access point of claim 6 wherein the feedback network further includes a first voltage divider resistor connected between the supply voltage and a feedback input to the DC-to-DC converter, and a second voltage divider resistor connected between the feedback input and a ground voltage.

8. The access point of claim 7 wherein the selectable resistor and the supply control switch are in series between the supply voltage and the feedback input.

9. The access point of claim 1 wherein the supply control switch sets the supply voltage to a first supply voltage level for a first value of the control signal, and to a second supply voltage level for a second value of the control signal.

10. The access point of claim 1 wherein the control circuit sets a value of the control signal based on a modulation and coding scheme index of the radio frequency transmit signal.

11. The access point of claim 1 wherein the control circuit sets a value of the control signal based on detecting a simultaneous transmission of the radio frequency transmit signal and reception of a radio frequency receive signal.

12. The access point of claim 1 wherein the radio frequency transmit signal operates in a Wi-Fi 5 GHz band or a Wi-Fi 6 GHz band.

13. The access point of claim 1 wherein the control signal further controls at least one of a bias or a load line of the power amplifier.

14. A front-end module comprising:
a power amplifier powered by a supply voltage from a DC-to-DC converter, the power amplifier configured to amplify a radio frequency transmit signal; and
a supply control switch coupled to a feedback network for setting a voltage level of the supply voltage from the DC-to-DC converter, the supply control switch operable to receive a control signal from a control circuit of a system controller, the supply control switch operable to control the voltage level of the supply voltage based on the control signal.

15. The front-end module of claim 14 wherein the supply control switch controls an amount of saturated output power of the power amplifier based on the control signal.

16. The front-end module of claim 14 wherein the feedback network includes a selectable resistor in series with the supply control switch.

17. The front-end module of claim 16 wherein the feedback network further includes a first voltage divider resistor connected between the supply voltage and a feedback input to the DC-to-DC converter, and a second voltage divider resistor connected between the feedback input and a ground voltage.

18. The front-end module of claim 17 wherein the selectable resistor and the supply control switch are in series between the supply voltage and the feedback input.

19. A method of radio frequency signal communication, the method comprising:
receiving a feedback signal from a feedback network at a feedback input of a DC-to-DC converter;
generating a supply voltage based on the feedback signal using the DC-to-DC converter;
powering a power amplifier that amplifies a radio frequency transmit signal using the supply voltage, the power amplifier included on a front-end module;
providing a control signal to a supply control switch that is coupled to the feedback network, the supply control switch included on the front-end module; and
controlling a voltage level of the supply voltage based on the control signal using the supply control switch.

20. The method of claim 19 further comprising controlling an amount of saturated output power of the power amplifier based on the control signal using the supply control switch controls.
